(19) United States
(12) Patent Application Publication
(10) Pub. No.: US 2024/0021353 A1
(43) Pub. Date: Jan. 18, 2024

(54) THREE-DIMENSIONAL VERTICAL CO-SPIRAL INDUCTORS

(71) Applicant: QUALCOMM Incorporated, San Diego, CA (US)

(72) Inventors: Jonghae KIM, San Diego, CA (US); Je-Hsiung LAN, San Diego, CA (US); Kai LIU, Phoenix, AZ (US); Ranadeep DUTTA, Del Mar, CA (US)

(21) Appl. No.: 17/812,772

(22) Filed: Jul. 15, 2022

(51) Int. Cl. H01F 17/00; H01F 27/28

(52) U.S. Cl. CPC H01F 17/0013; H01F 27/2804; H01F 2027/2809

(57) ABSTRACT

One or more aspects include apparatuses, systems including co-spiral inductors and methods for fabricating the same. In at least one aspect, a co-spiral inductor includes a plurality of turns, each of the plurality of turns being displaced both vertically and horizontally from a next successive turn. The plurality of turns is formed from traces on different metal layers formed on a substrate. The co-spiral inductor includes a plurality of insulators configured to electrically insulate each of the plurality of turns. The co-spiral inductor includes a plurality of interconnects configured to couple each of the plurality of turns to at least one other turn.

### FIELD OF DISCLOSURE

The present disclosure relates generally to semiconductor devices including electronic devices incorporating the semiconductor devices, and more specifically, but not exclusively, to inductors, three-dimensional (3D) inductors, related devices, and fabrication techniques thereof.

### BACKGROUND

Integrated circuit (IC) technology has achieved great strides in advancing computing power through miniaturization of active components. The various packaging technologies such as flip-chip devices can be found in many electronic devices, including processors, servers, radio frequency (RF), RF front end (RFFE) and other integrated circuits. Advanced packaging and processing techniques allow for system on a chip (SOC) devices, which. may include multiple function blocks, with each function block designed to perform a specific function, such as, for example, a microprocessor function, a graphics processing unit (GPU) function, a communications function (e.g., 5G, LTE, Wi-Fi, Bluetooth, and other communications), and the like.

Additionally, passive components can have a significant impact on integrated circuit and/or packaging technologies. For example, high-density inductors can be used to reduce design footprint for RFFE applications and to increase inductance-density. The IC/packaging technology will have many metal layers for inductor routing. However, higher-density inductors may have a critical drawback of Self Resonant Frequency (SRF) reduction, which can impact the inductor and overall IC performance.

Accordingly, there is a need for systems, apparatuses and methods that overcome the deficiencies of conventional inductor designs including the methods, systems and apparatuses provided herein in the following disclosure.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In an aspect, an apparatus including a co-spiral inductor comprising: a plurality of turns, each of the plurality of turns being displaced both vertically and horizontally from a next successive turn, wherein the plurality of turns is formed from traces on different metal layers formed on a substrate; a plurality of insulators configured to electrically insulate each of the plurality of turns; and a plurality of interconnects configured to couple each of the plurality of turns to at least one other turn.

In an aspect, a method for fabricating an apparatus including a co-spiral inductor includes forming a plurality of turns, each of the plurality of turns being displaced both vertically and horizontally from a next successive turn, wherein the plurality of turns is formed from traces on different metal layers formed on a substrate; forming a plurality of insulators configured to electrically insulate each of the plurality of turns; and forming a plurality of interconnects configured to couple each of the plurality of turns to at least one other turn.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 illustrates a partial cross-sectional view of an apparatus in accordance with one or more aspects of the disclosure.

FIG. 2 illustrates a perspective view of a co-spiral inductor in accordance with one or more aspects of the disclosure.

FIG. 3 illustrates graphs comparing self-resonant frequency (SRF) and quality factor (Q) for various inductor designs in accordance with one or more aspects of the disclosure.

FIG. 4 illustrates a perspective view of a co-spiral inductor in accordance with one or more aspects of the disclosure.

FIG. 5 illustrates graphs comparing self-resonant frequency (SRF) and quality factor (Q) for the inductor designs of FIG. 2 and FIG. 4.

FIG. 6 illustrates a partial cross-sectional view of an apparatus in accordance with one or more aspects of the disclosure.

FIG. 7 illustrates an apparatus including co-spiral inductors in accordance with one or more aspects of the disclosure.

FIGS. 8A-D illustrate partial cross-sectional and perspective views of apparatuses in accordance with one or more aspects of the disclosure.

FIG. 9 illustrates components of an integrated device in accordance with one or more aspects of the disclosure.

FIG. 10 illustrates a flowchart of a method in accordance with one or more aspects of the disclosure.

FIG. 11 illustrates an exemplary mobile device in accordance with one or more aspects of the disclosure.

FIG. 12 illustrates various electronic devices that may be integrated with any of the aforementioned devices in accordance with one or more aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In accordance with at least some of the various aspects disclosed, a 3D tapered vertical co-spiral inductor design to mitigate/resolve SRF improvement at high-density inductor. The requirements to implement this invention are (1) high-Q/high density inductor with higher SRF and smaller formfactor, (2) more inductor routing layers (e.g., four thick metal layers) for higher-density, and (3) small design footprint driven by high density inductor.

In accordance with at least some of the various aspects disclosed, designs for high density/High-Q inductor with high SRF are provided. the 3D vertical co-spiral inductor is designed to obtain high density inductor. The 3D tapered vertical co-spiral inductor is designed to increase SRF. Outside metal traces thicknesses (out of co-spiral aperture) are increased by the disclosed metal stacking and associated methods for fabrication. In accordance with at least some of the various aspects disclosed, improvements include over 11% of inductor Q-factor with tolerable reductions of SRF (4%) and inductance (2%).

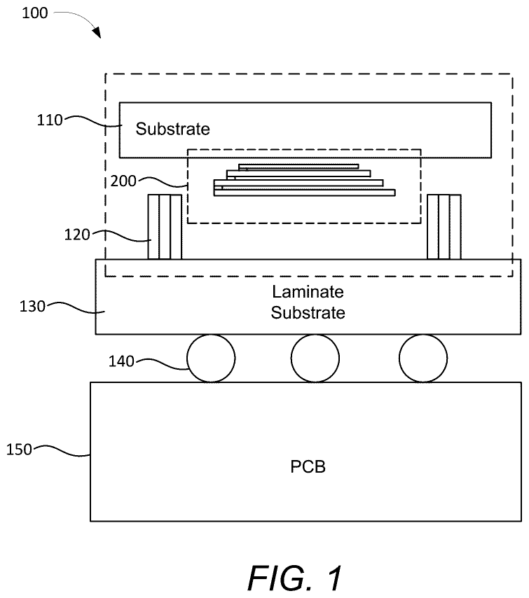

FIG. 1 illustrates a partial cross-sectional view of an apparatus 100 in accordance with one or more aspects of the disclosure. As illustrated the apparatus 100 may include a substrate 110 (e.g., a die, filter die, integrated passive device) and a co-spiral inductor 200, which in some aspects may be formed as part of the substrate, e.g., in a flip-chip configuration. Additional details will be discussed in the following disclosure. A first set of connectors 120, which may be die bumps, copper pillars, or any suitable connector, configured to couple the substrate 110 to the package substrate 130, which in some aspects may comprise a laminate substrate. The package substrate 130 is coupled to a printed circuit board (PCB) 150 by a second set of connectors 140, which may be solder balls or any suitable connector. In some aspects, the substrate 110 may be configured as an RFFE or other RF circuit including co-spiral inductor 200. In some aspects, the package substrate 130 is configured to couple (e.g., fan out, change in pitch, etc.) the substrate to the PCB 150 to form part of a larger scale apparatus (e.g., cellular phone, tablet, other mobile devices, etc.), as is known in the art. It will be appreciated that the illustration of apparatus 100 is provided solely to aid in the discussion of the various aspects disclosed and should not be construed to limit the various aspects disclosed. For example, the apparatus 100, in some aspects, may not have a PCB 150 or may have multiple PCBs 150, and/or package substrates 130 and/or substrates 110. The package substrate 130 may include additional active or passive components and may provide routing between elements of the substrate 110. Further, in some aspects, the apparatus 100 may not have package substrate 130 and the first set of connectors 120 may be directly coupled to the PCB 150. Accordingly, the various aspects disclosed are not limited to the illustrated example of FIG. 1.

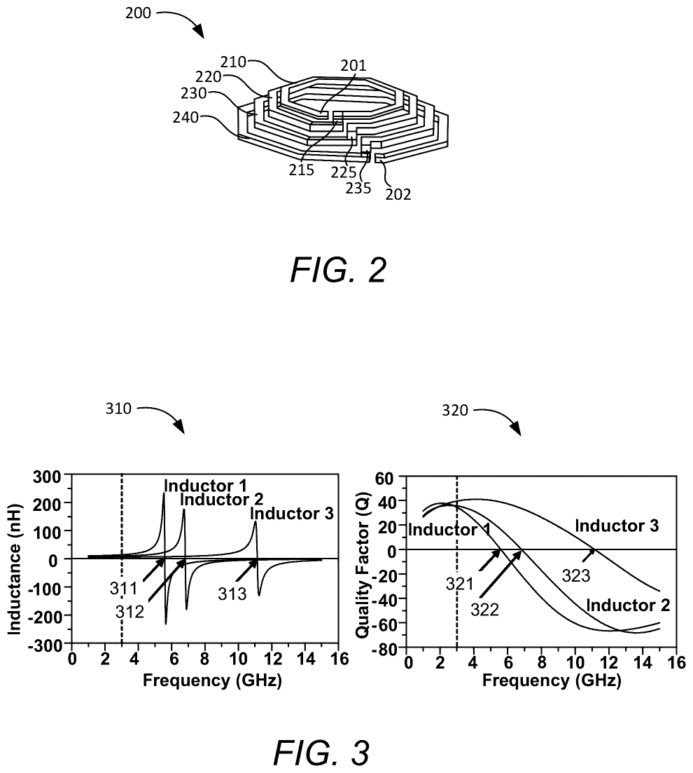

FIG. 2 illustrates a perspective view of a co-spiral inductor 200 in accordance with one or more aspects of the disclosure. In the illustrated configuration the co-spiral inductor 200 has a first terminal 201 and a second terminal 202 which form coupling points for the co-spiral inductor 200. The first terminal is part of the first turn 210 of the co-spiral inductor 200, which as illustrated, is formed from a first trace in a first metal layer. A second turn 220 of the co-spiral inductor 200, which as illustrated, is formed from a second trace in a second metal layer A third turn 230 of the co-spiral inductor 200, which as illustrated, is formed from a third trace in a third metal layer. A fourth turn 240 of the co-spiral inductor 200, which as illustrated, is formed from a fourth trace in a fourth metal layer and terminates at the second terminal 202. The first turn 210 is coupled in series with the second turn 220 by a first interconnect 215. The second turn 220 is coupled in series with the third turn 230 by a second interconnect 225. The fourth turn 240 is coupled in series with the third turn 230 by a third interconnect 235. Accordingly, as illustrated, co-spiral inductor 200 has four turns coupled in series. Additionally, it will be appreciated that each turn of co-spiral inductor 200 is displaced both vertically and horizontally from the next successive turn, such that the turn have a generally tapered or stepped 3D form. Further, the traces are generally concentric in form, so that co-spiral inductor 200 has turns that are generally tapered and concentric. In some aspects, this configuration may be referred to as a vertical 3D co-spiral inductor or generally as a co-spiral inductor. However, it will be appreciated that the various aspects disclosed are not limited to the illustrated configuration. For example, various aspects may include more or less traces/turns. The traces/turns may be hexagon, circular, square, rectangular, or any other geometric shape. In some aspects, the co-spiral inductor 200 may have different geometric shapes for different traces/turns. In some aspects, one or more traces/turns may be vertically and/or horizontally aligned. In some aspects, two or more traces/turns may be coupled in parallel. Accordingly, the various aspects disclosed are not limited to the illustrated example provided in FIG. 2.

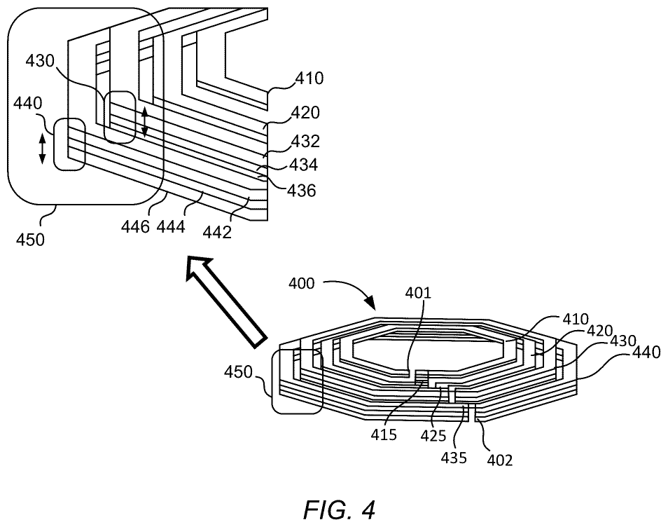

FIG. 3 illustrates graphs comparing self-resonant frequency (SRF) and quality factor (Q) for various inductor designs in accordance with one or more aspects of the disclosure. As discussed in the foregoing, the various co-spiral inductor configurations disclosed herein provide for increase SRF and for high Q inductors. Graph 310 illustrates a comparison of two conventional spiral inductors, inductor 1, and inductor 2, with inductor 3, which is a co-spiral inductor design (e.g., co-spiral inductor 200). In Graph 310, lines 311, 312 and 313 illustrate the change in inductance vs. frequency for inductors 1, 2 and 3, respectively. As can be seen from Graph 310, the SFR inductance peaks are substantially lower for inductor 1 and inductor 2, than for inductor 3. In Graph 320, lines 321, 322 and 323 illustrate the change in Q vs. frequency for inductors 1, 2 and 3, respectively. As can be seen from Graph 320, the quality factor (Q) is lower for inductor 1 and inductor 2, than for inductor 3, as frequency increases. In particular, the co-spiral inductor design of inductor 3 can provide a Q>30 over a much larger frequency range than conventional spiral inductors 1 and 2.

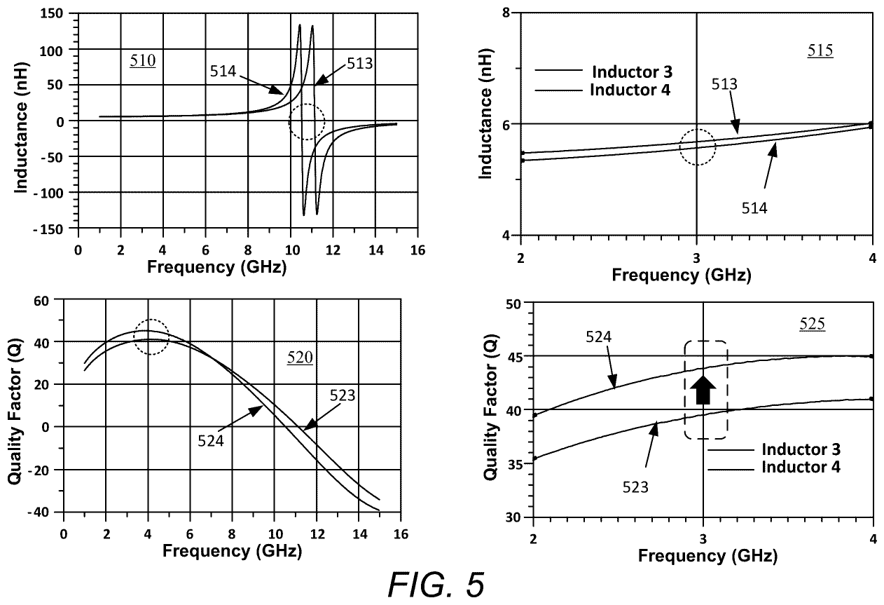

FIG. 4 illustrates a perspective view of a co-spiral inductor 400 in accordance with one or more aspects of the disclosure. In the illustrated configuration the co-spiral inductor 400 has a first terminal 401 and a second terminal 402, which form coupling points for the co-spiral inductor 400. The first terminal is part of the first turn 410 of the co-spiral inductor 400, which as illustrated, us formed from a first trace in a first metal layer. A second turn 420 of the co-spiral inductor 400 is formed from a second trace in a second metal layer. A turn 430 of the co-spiral inductor 400 is formed from at least in part from a third trace in a third metal layer. A fourth turn 440 of the co-spiral inductor 400 is formed at least in part from a fourth trace in a fourth metal layer and terminates at the second terminal 402. The first turn 410 is coupled in series with the second turn 420 by a first interconnect 415. The second turn 420 is coupled in series with the third turn 430 by a second interconnect 425. The fourth turn 440 is coupled in series with the third turn 430 by a third interconnect 435. Accordingly, as illustrated, co-spiral inductor 400 has four turns coupled in series. Further, it will be appreciated that at least two turn of co-spiral inductor 400 are displaced both vertically and horizontally from the next successive trace and that the traces have a generally tapered or stepped 3D form. However, co-spiral inductor 400 has one or more turns (e.g., turn 440 and turn 430) that include multiple metal layers coupled together. For example, as illustrated in the detail section 450, the third turn 430 may include a trace 432 on the second metal layer and a trace 436 on third metal layer coupled by a trace 434 (e.g., via bar) on a first via layer disposed between the second metal layer and the third metal layer. Additionally, as illustrated in the detail section 450, the fourth turn 440 may include a trace 442 on the third metal layer and a trace 446 on fourth metal layer coupled by a trace 444 (e.g., via bar) on a second via layer disposed between the third metal layer and the fourth metal layer. Accordingly, in some aspects, at least one turn (e.g., the third turn 430 and the fourth turn 440, as illustrated) is formed in part from a same metal layer as at least one other turn (e.g., 436 and 442). Even with a portion of the turns being formed from stacked metal layers, the traces are generally concentric in form and still have an a vertical (at least for a portion of each turn) and horizontal offset, so that co-spiral inductor 400 has turns that are generally tapered and concentric. In some aspects, this configuration may be referred to as a vertical 3D co-spiral inductor or generally as a co-spiral inductor. However, it will be appreciated that the various aspects disclosed are not limited to the illustrated configuration. For example, various aspects may include more or less traces/turns. The traces/turns may be hexagon, circular, square, rectangular, or any other geometric shape. In some aspects, the co-spiral inductor 400 may have different geometric shapes for different traces/turns. In some aspects, one or more traces/turns may be vertically and/or horizontally aligned. In some aspects, two or more traces/turns may be coupled in parallel. Further, there may be more or less stacked metal layers in the outer turns than in the illustrated example. Accordingly, the various aspects disclosed are not limited to the illustrated example provided in FIG. 4.

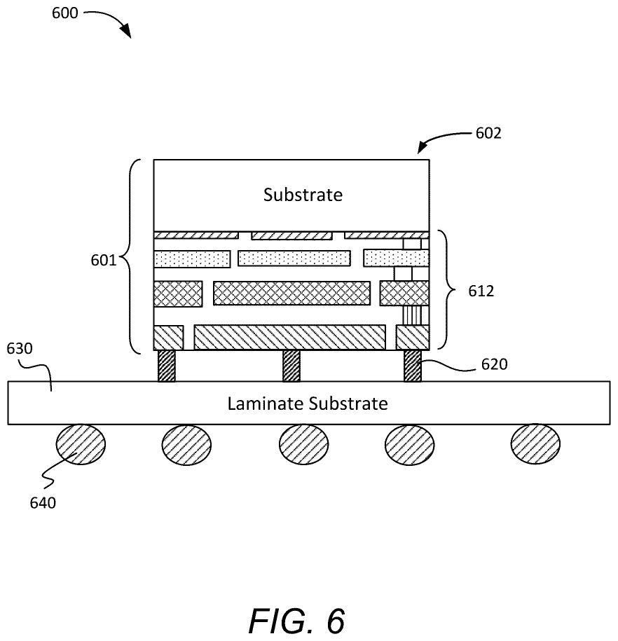

FIG. 5 illustrates graphs comparing self-resonant frequency (SRF) and quality factor (Q) for the inductor designs of FIG. 2, inductor 3 and FIG. 4, inductor 4, in accordance with one or more aspects of the disclosure. As discussed in the foregoing, the various co-spiral inductor configurations disclosed herein provide for increase SRF and for high Q inductors. Graph 510 illustrates a comparison of two co-spiral inductors, inductor 3 (e.g., co-spiral inductor 200), and inductor 4 (e.g., co-spiral inductor 400). In Graph 510, lines 513 and 514 illustrate the change in inductance vs. frequency for inductors 3 and 4, respectively. As can be seen from Graph 510, the SFR inductance peaks are slightly lower for inductor 4 than for inductor 3, however both are significantly higher than the conventional inductors discussed previously. Graph 515 illustrates an expanded plot of inductance vs. frequency for inductors 3 and 4 around frequencies of interest (e.g., 2 GHz to 4 GHz). As, can be seen from lines 513 and 514, the inductance difference is relatively small over the illustrated frequency range, which is well below the SFR inductance peaks. In Graph 520, lines 523 and 524 illustrate the change in Q vs. frequency for inductors 3 and 4, respectively. As can be seen from Graph 520, the quality factor (Q) is slightly higher for inductor 4 at lower frequencies and slightly higher for inductor 3 at higher frequencies. However, it will be appreciated that both inductor 3 and inductor 4 can provide a Q>30 over a much larger frequency range than conventional spiral inductors 1 and 2, discussed in the foregoing. Graph 525 illustrates an expanded plot of Q vs. frequency for inductors 3 and 4 around frequencies of interest (e.g., 2 GHz to 4 GHz). As, can be seen from lines 523 and 524, the quality factor (Q) is improved for inductor 4 over the illustrated frequency range. Table 1 below provides for a comparison of the inductors 3 and 4, in accordance with one or more aspects of the disclosure. As can be seen from the table below and consistent with the graphs of FIG. 5, the SFR of inductor 4 is slightly reduced (−4%), as is the inductance (−2%), however the Q of inductor 4 is increased by 11%.

TABLE 1

| | Inductor 3 | Inductor 4 | Difference |
|---|---|---|---|
| SRF | 11.1 | 10.65 | −4% |
| Inductance (nH) | 5.683 | 5.567 | −2% |
| Q | 39.3 | 43.9 | +11% |

It will be appreciated that the foregoing graphs and values are provided merely for illustration and discussion of the various aspects disclosed and should not be construed to limit the various aspects to the values or configurations illustrated. These comparisons are used to show in general the design of co-spiral inductor 200 has an increased SFR, while the design of co-spiral inductor 400 has an increased Q. Variations of the designs may be made by one skilled in the art to achieve the desired results noting the tradeoff of SFR vs. Q, as discussed herein.

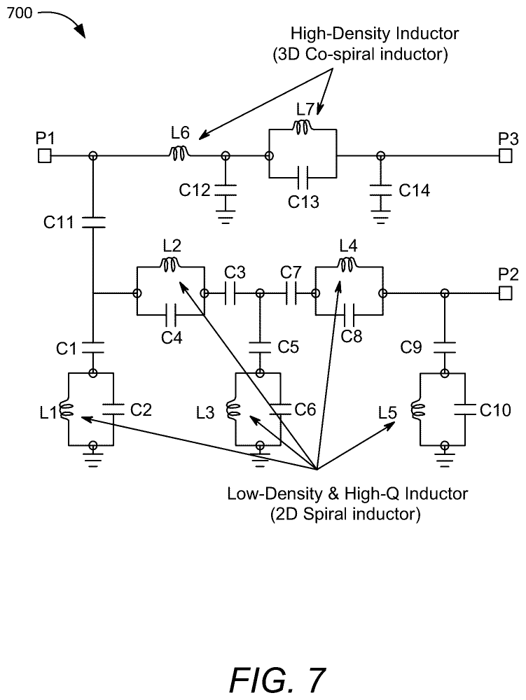

FIG. 6 illustrates a partial cross-sectional view of an apparatus 600 in accordance with one or more aspects of the disclosure. As illustrated the apparatus 600 may include a hybrid integrated passive (HIP) device 601 which includes a substrate 602 and various metal layers 612 (e.g., back end of line (BEOL) stack or the BEOL stack and one or more redistribution layers (RDL)). The various metal layers 612 can be used to form one or more co-spiral inductors as disclosed herein. Additionally, the apparatus 600, may be coupled to a device including an active component (e.g., a CMOS IC) integrated with a HIP device 601 which includes a substrate 602 and various metal layers 612 which can be used to form one or more co-spiral inductors as disclosed herein. It will be appreciated that in various aspects, one or more HIP devices 601 may both be mounted to package substrate 630 by connectors 620. The one or more HIP devices 601 may be interconnected by the package substrate 630 to allow for increased functionality, including in some aspects SoC devices. The package substrate 630, which in some aspects may comprise a laminate substrate, includes connectors 640 which can be used to fan out connections from the one or more HIP devices 601 and allow for connection to further external components and/or devices (e.g., PCB, etc.) as is known in the art. However, it will be appreciated that the various aspects disclosed are not limited to these illustrated components, devices and/or arrangements. For example, in accordance with some aspects of the disclosure, the apparatus may be a radio frequency (RF) filter, a RF front end (RFFE) circuit, a power combiner, diplexer, combinations thereof and similar components that can use one or more co-spiral inductors as disclosed herein. It will be appreciated that the illustration of apparatus 600 is provided solely to aid in the discussion of the various aspects disclosed and should not be construed to limit the various aspects disclosed. For example, the apparatus 600, in some aspects, may include additional active and/or passive components/devices or may be limited to a single component/device. Accordingly, the various aspects disclosed are not limited to the illustrated example of FIG. 6.

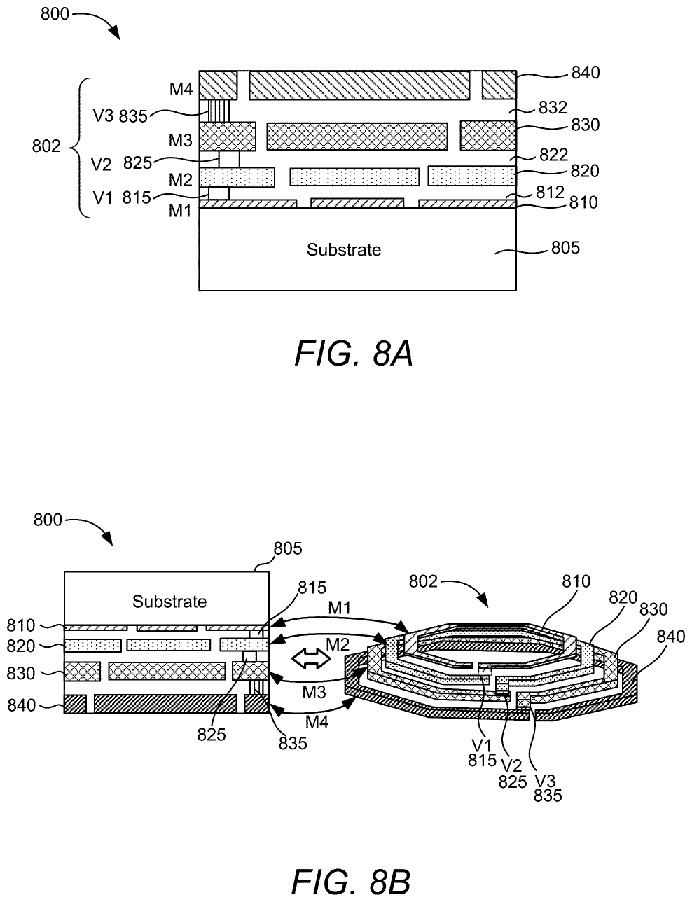

FIG. 7 illustrates an apparatus 700 including co-spiral inductors in accordance with one or more aspects of the disclosure. As illustrated, apparatus 700 is configured as a diplexer with a common port P1 and two frequency specific ports P2 and P3. In the illustrated example, inductors L1, L2, L3, L4 and L5 along with capacitors C1 to C11 are configured to form a high pass filter. Inductors L1 to L5 may be low density high Q 2D spiral inductors, which each may be formed on an individual metal layer of apparatus 700 and may have relatively low inductance (e.g., on the order of 0.6 nH to 1.1 nH) and a Q>40. Inductors L6 and L7 along with capacitors C12 to C14 are configured to form a low pass filter. Inductors L6 to L7 may be high density high Q 3D co-spiral inductors, which may be formed on multiple metal layers of apparatus 700, as disclosed herein. Inductors L6 to L7 may have relatively high inductance (e.g., on the order of 5 nH to 11 nH) and a Q>30. The various design details and configurations of diplexer circuits are known, so further discussion will be limited. It will be appreciated that the example configuration of the apparatus 700 was provided merely as an example of an implementation of co-spiral inductors, as disclosed herein, along with standard components and circuit designs. Accordingly, the various aspects disclosed are not limited to this example configuration.

In order to fully illustrate aspects of the design of the present disclosure, methods of fabrication are presented. Other methods of fabrication are possible, and discussed fabrication methods are presented only to aid understanding of the concepts disclosed herein.

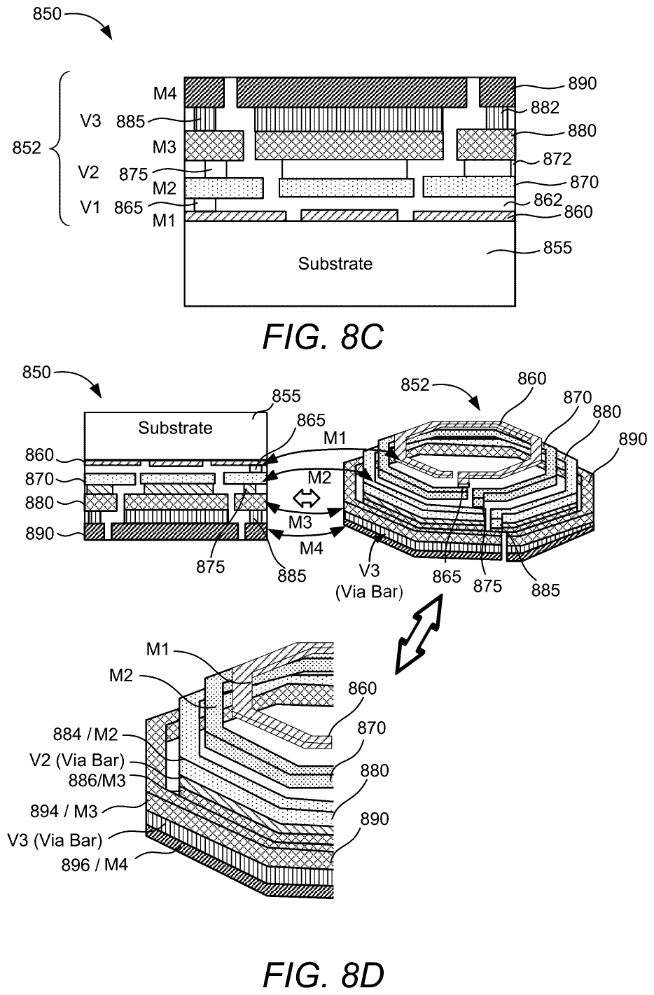

FIGS. 8A to 8D illustrate various partial cross-sectional and perspective views of apparatuses in accordance with one or more aspects of the disclosure. Referring to FIG. 8A, an apparatus 800 is illustrated with a cross-sectional inductor structure view of a co-spiral inductor 802 in accordance with one or more aspects of the disclosure. In the illustrated configuration the co-spiral inductor 802 has a first turn 810, a second turn 820, a third turn 830 and a fourth turn 840 of the co-spiral inductor 802, which as illustrated, are each formed in different metal layers (e.g., M1-M4, formed in the BEOL only or BEOL+RDL). It will be appreciated that, as illustrated, the apparatus 800 may be inverted for fabrication to allow for the depositing of successive metal layers and insulating layers on the substrate 805 to form the co-spiral inductor 802. Accordingly, in some aspects, the co-spiral inductor 802 may be formed from a plurality of turns (e.g., 810, 820, 830, 840) with each of the plurality of turns being displaced both vertically and horizontally from a next successive turn. The deposited insulating layers form a plurality of insulators (e.g., 812, 822, 832) configured to electrically insulate each of the plurality of turns. Additionally, the fabrication process includes forming a plurality of interconnects (e.g., 815, 825, and 835) configured to couple each of the plurality of turns to at least one other turn, which may be formed at least in part by vias V1-V3, respectively. In one or more aspects, the plurality of turns (e.g., 810, 820, 830, 840) and plurality of interconnects (e.g., 815, 825, and 835) may be formed by any suitable conductor and in some aspects may be formed of one or more of copper (Cu), silver (Ag), gold (Au), nickel (Ni), platinum (Pl), aluminum (Al), Titanium (Ti), tin (Sn) and alloys or combinations thereof. In one or more aspects, the plurality of insulators (e.g., 812, 822, 832) is formed of one or more of silicon dioxide (SiO2), an organic polymeric dielectric, polyimide (PI), polynorbornene, benzocyclobutene (BCB), polytetrafluoroethylene (PTFE), Polybenzoxazoles (PBO), or silicone based polymeric dielectrics. In one or more aspects, the substrate 805 is formed of one or more of silicon (Si), High-resistivity silicon (HRSi), glass, aluminum oxide (Alumina), compounds or combinations thereof. It will be the various materials provided herein are merely examples of suitable materials and not an exhaustive list of all suitable materials. Accordingly, the various aspects disclosed are not limited to the example materials provided herein and one skilled in the art may substitute other materials that have the same functionality, such as, a conductor, insulator, etc.

FIG. 8B illustrates a cross-sectional inductor structure view and corresponding perspective view of the co-spiral inductor 802 in accordance with one or more aspects of the disclosure. In the illustrated configuration the apparatus 800 has been flipped to allow for subsequent processing, connection to additional components (e.g., package substrate, PCB, etc.). Accordingly, in some aspects, the co-spiral inductor 802 includes a plurality of turns (e.g., 810, 820, 830, 840), a plurality of insulators (e.g., 812, 822, 832) and a plurality of interconnects (e.g., 815, 825, 835), as discussed in relation to FIG. 8A. As illustrated in the perspective view, in co-spiral inductor 802, the first turn 810 is coupled in series with the second turn 820 by a first interconnect 815. The second turn 820 is coupled in series with the third turn 830 by a second interconnect 825. The fourth turn 840 is coupled in series with the third turn 830 by a third interconnect 835. Accordingly, as illustrated, co-spiral inductor 802 has four turns coupled in series. Additionally, it will be appreciated that each turn of co-spiral inductor 802 is displaced both vertically and horizontally from the next successive turn, such that the turn have a generally tapered or stepped 3D form. Further, the traces are generally concentric in form, so that co-spiral inductor 802 has turns that are generally tapered and concentric. However, it will be appreciated that the various aspects disclosed are not limited to the illustrated configuration. For example, various aspects may include more or less traces/turns. The traces/turns may be hexagon, circular, square, rectangular, or any other geometric shape. In some aspects, the co-spiral inductor 802 may have different geometric shapes for different traces/turns. In some aspects, one or more traces/turns may be vertically and/or horizontally aligned. In some aspects, two or more traces/turns may be coupled in parallel. Accordingly, the various aspects disclosed are not limited to the illustrated example provided in FIGS. 8A and 8B.

FIG. 8C illustrates an apparatus 850 in a cross-sectional inductor structure view of a co-spiral inductor 852 in accordance with one or more aspects of the disclosure. In the illustrated configuration the co-spiral inductor 852 has a first turn 860, a second turn 870, a third turn 880 and a fourth turn 890 of the co-spiral inductor 852, which as illustrated, are each formed in different metal layers (e.g., M1-M4, formed in the BEOL only or BEOL+RDL). It will be appreciated that, as illustrated, the apparatus 850 may be inverted for fabrication to allow for the depositing of successive metal layers and insulating layers on the substrate 855 to form the co-spiral inductor 852. Accordingly, in some aspects, the co-spiral inductor 852 may be formed from a plurality of turns (e.g., 860, 870, 880, 890) with each of the plurality of turns being displaced both vertically and horizontally from a next successive turn. The deposited insulating layers form a plurality of insulators (e.g., 862, 872, 882) configured to electrically insulate each of the plurality of turns. Additionally, the fabrication process includes forming a plurality of interconnects (e.g., 865, 875, and 885) configured to couple each of the plurality of turns to at least one other turn, which may be formed at least in part by vias V1-V3, respectively. It will be appreciated that one or more of the interconnects may be formed in part by via bars (e.g., V2 and V3), which may be used to couple stacked metal layers/multi-layer turns. In one or more aspects, the plurality of turns (e.g., 860, 870, 880, 890) and plurality of interconnects (e.g., 865, 875, and 885) may be formed by any suitable conductor and in some aspects may be formed of one or more of copper (Cu), silver (Ag), gold (Au), nickel (Ni), platinum (Pl), aluminum (Al), Titanium (Ti), tin (Sn) and alloys or combinations thereof. In one or more aspects, the plurality of insulators (e.g., 862, 872, 882) is formed of one or more of silicon dioxide (SiO2), an organic polymeric dielectric, polyimide (PI), polynorbornene, benzocyclobutene (BCB), polytetrafluoroethylene (PTFE), Polybenzoxazoles (PBO), or silicone based polymeric dielectrics. In one or more aspects, the substrate 855 is formed of one or more of silicon (Si), High-resistivity silicon (HRSi), glass, aluminum oxide (Alumina), compounds or combinations thereof.

FIG. 8D illustrates a cross-sectional inductor structure view and corresponding perspective view of the co-spiral inductor 852 in accordance with one or more aspects of the disclosure. In the illustrated configuration the apparatus 850 has been flipped to allow for subsequent processing, connection to additional components (e.g., package substrate, PCB, etc.). Accordingly, in some aspects, the co-spiral inductor 852 includes a plurality of turns (e.g., 860, 870, 880, 890), a plurality of insulators (e.g., 852, 872, 882) and a plurality of interconnects (e.g., 865, 875, 885), as discussed in relation to FIG. 8C. As illustrated in the perspective view, in co-spiral inductor 852, the first turn 860 is coupled in series with the second turn 870 by a first interconnect 865. The second turn 870 is coupled in series with the third turn 880 by a second interconnect 875. The fourth turn 890 is coupled in series with the third turn 880 by a third interconnect 885. Accordingly, as illustrated, co-spiral inductor 852 has four turns coupled in series. Further, it will be appreciated that at least two turn of co-spiral inductor 852 are displaced both vertically and horizontally from the next successive trace and that the traces have a generally tapered or stepped 3D form. However, co-spiral inductor 852 has one or more turns (e.g., turn 890 and turn 880) that include multiple metal layers coupled together. For example, as illustrated in the detail section, the third turn 880 may include a trace 884 on the second metal layer and a trace 886 on third metal layer coupled by via bar V2 (e.g., a via/metal layer) disposed between the second metal layer M2 and the third metal layer M3. Additionally, as illustrated in the detail section, the fourth turn 890 may include a trace 894 on the third metal layer and a trace 896 on fourth metal layer coupled by via bar V3 (e.g., a via/metal layer) disposed between the third metal layer M3 and the fourth metal layer M4. Accordingly, in some aspects, at least one turn (e.g., the third turn 880 and the fourth turn 890, as illustrated) is formed in part from a same metal layer as at least one other turn (e.g., 886 and 894). Even with a portion of the turns being formed from stacked metal layers, the traces are generally concentric in form and still have an a vertical (at least for a portion of each turn) and horizontal offset, so that co-spiral inductor 852 has turns that are generally tapered and concentric. However, it will be appreciated that the various aspects disclosed are not limited to the illustrated configuration. For example, various aspects may include more or less traces/turns. The traces/turns may be hexagon, circular, square, rectangular, or any other geometric shape. In some aspects, the co-spiral inductor 852 may have different geometric shapes for different traces/turns. In some aspects, one or more traces/turns may be vertically and/or horizontally aligned. In some aspects, two or more traces/turns may be coupled in parallel. Accordingly, the various aspects disclosed are not limited to the illustrated example provided in FIGS. 8C and 8D.

It will be appreciated that the foregoing discussion example fabrication processes was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

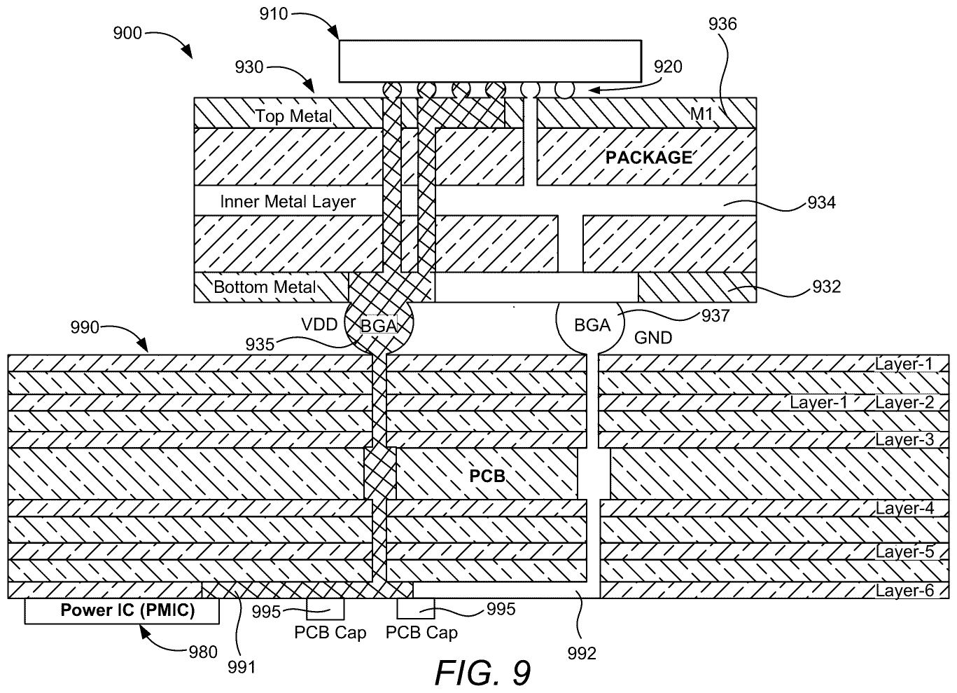

FIG. 9 illustrates components of an apparatus 900 according to one or more aspects of the disclosure. Regardless of the various configurations of the various aspects discussed herein, it will be appreciated that the package 930 may be configured to couple the device 910 including at least one co-spiral inductor, to a PCB 990. For example, device 910 may be similar to any devices/combinations (e.g., 100 and 200, 600, 700, 800, 850) including at least one co-spiral inductor (e.g., 200, 400, 802, 852). The PCB 990 is also coupled to a power supply 980 (e.g., a power management integrated circuit (PMIC)), which allows the package 930 and the device 910 to be electrically coupled to the PMIC 980. Specifically, one or more power supply (VDD) lines 991 and one or more ground (GND) lines 992 may be coupled to the PMIC 980 to distribute power to the PCB 990, package 930 via VDD BGA pin 935 and GND BGA pin 937 and to the device 910 via connectors 920 (which may be plated UBMs of various sizes and pitches, coupled to the top metal layer/M1 layer 936 of package 930, and other metal layers such as intermetal layer 934 and bottom metal layer 932, as discussed above). The VDD line 991 and GND line 992 each may be formed from traces, shapes, or patterns in one or more metal layers of the PCB 990 (e.g., layers 1-6) coupled by one or more vias through insulating layers separating the metal layers 1-6 in the PCB 990. The PCB 990 may have one or more PCB capacitors 995 (PCB cap) that can be used to condition the power supply signals, as is known to those skilled in the art. Additional connections and devices may be coupled to and/or pass through the PCB 990 to the package 930 via one or more additional BGA balls/pins (not illustrated) on the package 930. It will be appreciated that the illustrated configuration and descriptions are provided merely to aid in the explanation of the various aspects disclosed herein. For example, the PCB 990 may have more or less metal and insulating layers, there may be multiple lines providing power to the various components, etc. Accordingly, the forgoing illustrative examples and associated figures should not be construed to limit the various aspects disclosed and claimed herein

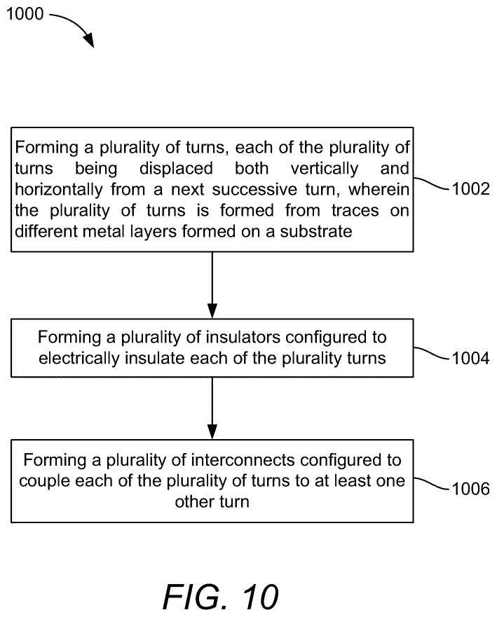

It will be appreciated from the foregoing that there are various methods for fabricating devices including co-spiral inductors disclosed herein. FIG. 10 illustrates a flowchart of a method 1000 for fabricating an apparatus including a co-spiral inductor. The method 1000 may include, in block 1002, forming a plurality of turns, each of the plurality of turns being displaced both vertically and horizontally from a next successive turn, wherein the plurality of turns is formed from traces on different metal layers formed on a substrate. The method 1000 may include, in block 1004, forming a plurality of insulators configured to electrically insulate each of the plurality of turns. The method 1000 may include, in block 1006, forming a plurality of interconnects configured to couple each of the plurality of turns to at least one other turn.

Accordingly, it will be appreciated from the foregoing disclosure that additional processes for fabricating the various aspects disclosed herein will be apparent to those skilled in the art and a literal rendition of the processes discussed above will not be provided or illustrated in the included drawings. It will be appreciated that the sequence of the fabrication processes are not necessarily in any order and later processes may be discussed earlier to provide an example of the breadth of the various aspects disclosed.

In accordance with the various aspects disclosed herein, at least one aspect includes a method for fabricating an apparatus (e.g., 100, 600, 700 and 910) including a co-spiral inductor (e.g., 200, 400) including: a plurality of turns (e.g., 210, 220, 230, 240, 410, 420, 430 and 440), each of the plurality of turns being displaced both vertically and horizontally from a next successive turn (e.g., forming the tapered concentric 3D co-spiral configuration). Additionally, the plurality of turns can be formed from traces on different metal layers formed on a substrate (e.g., 100). A plurality of insulators (e.g., insulating layers illustrated in FIGS. 8A-8D) is configured to electrically insulate each of the plurality of turns and a plurality of interconnects (e.g., 215, 225, 235, 415, 425 and 435) is configured to couple each of the plurality of turns to at least one other turn.

Among the various technical advantages, the various aspects disclosed provide, in at least some aspects, the feature(s) tapered concentric 3D co-spiral configuration provided by each of the plurality of turns being displaced both vertically and horizontally from a next successive turn allow for increased inductor density along increased SRF with high-Q values. It will be appreciated the tapered 3D co-spiral inductors disclosed herein optimize key inductor performance metrics (e.g., inductor-density, SRF, and Q-factor) simultaneously, because the inductor-density is inversely proportional to SRF in conventional inductor designs. Other technical advantages will be recognized from various aspects disclosed herein and these technical advantages are merely provided as examples and should not be construed to limit any of the various aspects disclosed herein.

Further aspects may include one or more of the following features discussed in the various example aspects. In one or more aspects, the plurality of interconnects is configured to couple each of the plurality of turns in series. In one or more aspects, at least one of the plurality of interconnects is configured to couple at least two of the plurality of turns in parallel. In one or more aspects, the plurality of turns are generally hexagonal, circular, square, or rectangular in shape. In one or more aspects, the plurality of turns are generally tapered with a first turn of the plurality of turns having a smallest length and a last turn of the plurality of turns having a greatest length. In one or more aspects, each of the plurality of turns is formed on a separate layer from any other turn of the plurality of turns.

In one or more aspects, the substrate is part of a flip-chip. In one or more aspects, the apparatus includes a package substrate coupled to the substrate on a first side of the package substrate that faces the co-spiral inductor. In one or more aspects, the apparatus includes a printed circuit board coupled to the package substrate on a second side of the package substrate that is opposite the first side.

In one or more aspects, at least two of the plurality of turns have different thicknesses. In one or more aspects, a first turn closest to the substrate has a smaller thickness than a last turn furthest away from the substrate. In one or more aspects, at least one outer turn is formed from at least two stacked metal layers of the different metal layers. In one or more aspects, the at least one outer turn has at least one via layer that couples the at least two stacked metal layers. In one or more aspects the at least two stacked metal layers is a on a same metal layer as at least one other turn of the plurality of turns.

In one or more aspects, the plurality of insulators is formed of one or more of silicon dioxide (SiO2), an organic polymeric dielectric, polyimide (PI), polynorbornene, benzocyclobutene (BCB), polytetrafluoroethylene (PTFE), Polybenzoxazoles (PBO), or silicone based polymeric dielectrics. In one or more aspects, the plurality of turns is formed of one or more of copper (Cu), silver (Ag), gold (Au), nickel (Ni), platinum (Pl), aluminum (Al), Titanium (Ti), tin (Sn), alloys or combinations thereof. In one or more aspects, the substrate is formed of one or more of silicon (Si), High-resistivity silicon (HRSi), glass, aluminum oxide (Alumina), compounds or combinations thereof.

In one or more aspects, the apparatus comprises at least one of a hybrid integrated passive device (HIP), an active component integrated with a HIP, a radio frequency (RF) filter, a RF front end (RFFE) circuit, a power combiner, or a diplexer. In one or more aspects, the co-spiral inductor is formed in a back end of line (BEOL) stack or the BEOL stack and one or more redistribution layers (RDL). In one or more aspects, the apparatus is selected from a group comprising at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, or a device in an automotive vehicle.

The foregoing disclosed devices and functionalities may be designed and stored in computer files (e.g., register-transfer level (RTL), Geometric Data Stream (GDS) Gerber, and the like) stored on computer-readable media. Some or all such files may be provided to fabrication handlers who fabricate devices based on such files. Resulting products may include various components, including semiconductor wafers that are then cut into semiconductor die and packaged into semiconductor packages, integrated devices, package on package devices, system-on-chip devices, and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

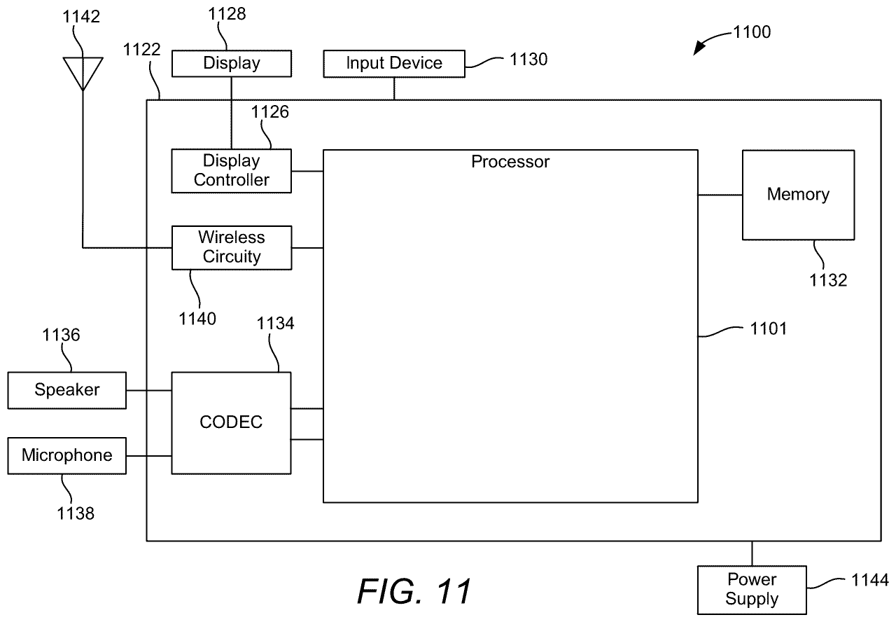

FIG. 11 illustrates an exemplary mobile device in accordance with some examples of the disclosure. Referring now to FIG. 11, a block diagram of a mobile device that is configured according to exemplary aspects is depicted and generally designated mobile device 1100. In some aspects, mobile device 1100 may be configured as a wireless communication device. As shown, mobile device 1100 includes processor 1101. Processor 1101 may be communicatively coupled to memory 1132 over a link, which may be a die-to-die or chip-to-chip link. Mobile device 1100 also includes display 1128 and display controller 1126, with display controller 1126 coupled to processor 1101 and to display 1128.

In some aspects, FIG. 11 may include coder/decoder (CODEC) 1134 (e.g., an audio and/or voice CODEC) coupled to processor 1101; speaker 1136 and microphone 1138 coupled to CODEC 1134; and wireless circuits 1140 (which may include a modem, RF circuitry, filters, etc., which may be implemented using one or more co-spiral inductors as disclosed herein) coupled to wireless antenna 1142 and to processor 1101.

In a particular aspect, where one or more of the above-mentioned blocks are present, processor 1101, display controller 1126, memory 1132, CODEC 1134, and wireless circuits 1140 can be included in a system-in-package or system-on-chip device 1122 which may be implemented in whole or part using techniques disclosed herein. Input device 1130 (e.g., physical, or virtual keyboard), power supply 1144 (e.g., battery), display 1128, input device 1130, speaker 1136, microphone 1138, wireless antenna 1142, and power supply 1144 may be external to system-on-chip device 1122 and may be coupled to a component of system-on-chip device 1122, such as an interface or a controller.

It should be noted that although FIG. 11 depicts a mobile device 1100, processor 1101 and memory 1132 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

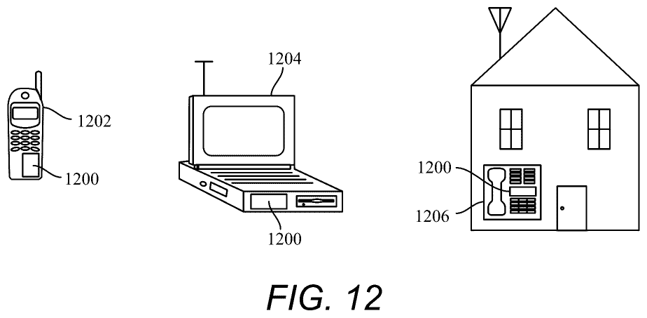

FIG. 12 illustrates various electronic devices that may be integrated with any of the aforementioned integrated device or semiconductor device accordance with various examples of the disclosure. For example, a mobile phone device 1202, a laptop computer device 1204, and a fixed location terminal device 1206 may each be considered generally user equipment (UE) and may include a co-spiral inductor 1200 as described herein. The co-spiral inductor 1200 may be, for example, any of the integrated circuits, dies, integrated devices, integrated device packages, integrated circuit devices, device packages, integrated circuit (IC) packages, package-on-package devices described herein. The devices 1202, 1204, 1206 illustrated in FIG. 12 are merely exemplary. Other electronic devices may also feature the co-spiral inductor 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., register-transfer level (RTL), Geometric Data Stream (GDS) Gerber, and the like) stored on computer-readable media. Some or all such files may be provided to fabrication handlers who fabricate devices based on such files. Resulting products may include semiconductor wafers that are then cut into semiconductor die and packaged into semiconductor packages, integrated devices, system-on-chip devices, and the like, which may then be employed in the various devices described herein.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-12 may be rearranged and/or combined into a single component, process, feature, or function or incorporated in several components, processes, or functions. Additional elements, components, processes, and/or functions may also be added without departing from the disclosure. It should also be noted that FIGS. 1-12 and corresponding description in the present disclosure are not limited to dies and/or ICs. In some implementations, FIGS. 1-12 and the corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a system in package (SiP), a system on chip (SoC), a package on package (PoP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (WiFi), and IEEE 802.15.4 (Zigbee®/Thread) or other protocols that may be used in a wireless communications network or a data communications network. Bluetooth® Low Energy (also known as Bluetooth® LE, BLE, and Bluetooth® Smart).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage, or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer, or an electronic circuit. In some examples, some or a plurality of the most important method actions can be performed by such an apparatus.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:
Clause 1. An apparatus including a co-spiral inductor comprising: a plurality of turns, each of the plurality of turns being displaced both vertically and horizontally from a next successive turn, wherein the plurality of turns is formed from traces on different metal layers formed on a substrate; a plurality of insulators configured to electrically insulate each of the plurality of turns; and a plurality of interconnects configured to couple each of the plurality of turns to at least one other turn.
Clause 2. The apparatus of clause 1, wherein the plurality of interconnects are configured to couple each of the plurality of turns in series.
Clause 3. The apparatus of any of clauses 1 to 2, wherein at least one of the plurality of interconnects is configured to couple at least two of the plurality of turns in parallel.
Clause 4. The apparatus of any of clauses 1 to 3, wherein the plurality of turns are hexagonal, circular, square, or rectangular in shape.
Clause 5. The apparatus of any of clauses 1 to 4, wherein the plurality of turns are generally tapered with a first turn of the plurality of turns having a smallest length and a last turn of the plurality of turns having a greatest length.
Clause 6. The apparatus of any of clauses 1 to 5, wherein each of the plurality of turns is formed on a separate layer from any other turn of the plurality of turns.
Clause 7. The apparatus of clause 6, wherein the substrate is part of a flip-chip.
Clause 8. The apparatus of clause 7, further comprising a package substrate coupled to the substrate on a first side of the package substrate that faces the co-spiral inductor.
Clause 9. The apparatus of clause 8, further comprising a printed circuit board coupled to the package substrate on a second side of the package substrate that is opposite the first side.
Clause 10. The apparatus of any of clauses 1 to 9, wherein at least two of the plurality of turns have different thicknesses.
Clause 11. The apparatus of clause 10, wherein a first turn closest to the substrate has a smaller thickness than a last turn furthest away from the substrate.
Clause 12. The apparatus of any of clauses 10 to 11, wherein at least one outer turn is formed from at least two stacked metal layers of different metal layers.
Clause 13. The apparatus of clause 12, wherein the at least one outer turn has at least one via layer that couples the at least two stacked metal layers.
Clause 14. The apparatus of any of clauses 12 to 13, wherein the at least one of the at least two stacked metal layers is a on a same metal layer as at least one other turn of the plurality of turns.
Clause 15. The apparatus of any of clauses 1 to 14, wherein the plurality of insulators is formed of one or more of silicon dioxide (SiO2), an organic polymeric dielectric, polyimide (PI), polynorbornene, benzocyclobutene (BCB), polytetrafluoroethylene (PTFE), Polybenzoxazoles (PBO), or silicone based polymeric dielectrics.
Clause 16. The apparatus of any of clauses 1 to 15, wherein the plurality of turns is formed of one or more of copper (Cu), silver (Ag), gold (Au), nickel (Ni), platinum (Pl), aluminum (Al), Titanium (Ti), tin (Sn), alloys or combinations thereof.
Clause 17. The apparatus of any of clauses 1 to 16, wherein the substrate is formed of one or more of silicon (Si), High-resistivity silicon (HRSi), glass, aluminum oxide (Alumina), compounds or combinations thereof.
Clause 18. The apparatus of any of clauses 1 to 17, wherein the apparatus comprises at least one of a hybrid integrated passive device (HIP), an active component integrated with a HIP, a radio frequency (RF) filter, a RF front end (RFFE) circuit, a power combiner, or a diplexer.
Clause 19. The apparatus of any of clauses 1 to 18, wherein the co-spiral inductor is formed in a back end of line (BEOL) stack or the BEOL stack and one or more redistribution layers (RDL).
Clause 20. The apparatus of any of clauses 1 to 19, wherein the apparatus is selected from a group comprising at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, or a device in an automotive vehicle.
Clause 21. A method for fabricating an apparatus including a co-spiral inductor, the method comprising: forming a plurality of turns, each of the plurality of turns being displaced both vertically and horizontally from a next successive turn, wherein the plurality of turns is formed from traces on different metal layers formed on a substrate; forming a plurality of insulators configured to electrically insulate each of the plurality of turns; and forming a plurality of interconnects configured to couple each of the plurality of turns to at least one other turn.
Clause 22. The method of clause 21, wherein the plurality of interconnects are configured to couple each of the plurality of turns in series.
Clause 23. The method of any of clauses 21 to 22, wherein at least one of the plurality of interconnects is configured to couple at least two of the plurality of turns in parallel.
Clause 24. The method of any of clauses 21 to 23, wherein the plurality of turns are hexagonal, circular, square, or rectangular in shape.
Clause 25. The method of any of clauses 21 to 24, wherein the plurality of turns are generally tapered with a first turn of the plurality of turns having a smallest length and a last turn of the plurality of turns having a greatest length.
Clause 26. The method of any of clauses 21 to 25, further comprising forming each of the plurality of turns on a separate layer from any other turn of the plurality of turns.
Clause 27. The method of any of clauses 21 to 26, wherein the substrate is part of a flip-chip.
Clause 28. The method of any of clauses 21 to 27, further comprising coupling a package substrate to the substrate on a first side of the package substrate that faces the co-spiral inductor.
Clause 29. The method of clause 28, further comprising coupling a printed circuit board to the package substrate on a second side of the package substrate that is opposite the first side.
Clause 30. The method of any of clauses 21 to 29, wherein at least two of the plurality of turns have different thicknesses.
Clause 31. The method of clause 30, wherein a first turn closest to the substrate has a smaller thickness than a last turn furthest away from the substrate.
Clause 32. The method of any of clauses 30 to 31, wherein at least one outer turn is formed from at least two stacked metal layers of different metal layers.
Clause 33. The method of clause 32, wherein the at least one outer turn has at least one via layer that couples the at least two stacked metal layers.
Clause 34. The method of any of clauses 32 to 33, wherein at least one of the at least two stacked metal layers is a on a same metal layer as at least one other turn of the plurality of turns.
Clause 35. The method of any of clauses 21 to 34, wherein the plurality of insulators is formed of one or more of silicon dioxide (SiO2), an organic polymeric dielectric, polyimide (PO, polynorbornene, benzocyclobutene (BCB), polytetrafluoroethylene (PTFE), Polybenzoxazoles (PBO), or silicone based polymeric dielectrics.
Clause 36. The method of any of clauses 21 to 35, wherein the plurality of turns is formed of one or more of copper (Cu), silver (Ag), gold (Au), nickel (Ni), platinum (Pl), aluminum (Al), Titanium (Ti), tin (Sn), alloys or combinations thereof.
Clause 37. The method of any of clauses 21 to 36, wherein the substrate is formed of one or more of silicon (Si), High-resistivity silicon (HRSi), glass, aluminum oxide (Alumina), compounds or combinations thereof.
Clause 38. The method of any of clauses 21 to 37, wherein the apparatus comprises at least one of a hybrid integrated passive device (HIP), an active component integrated with a HIP, a radio frequency (RF) filter, a RF front end (RFFE) circuit, a power combiner, or a diplexer.
Clause 39. The method of any of clauses 21 to 38, further comprising forming the co-spiral inductor in a back end of line (BEOL) stack or the BEOL stack and one or more redistribution layers (RDL).
Clause 40. The method of any of clauses 21 to 39, wherein the apparatus is selected from a group comprising at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, or a device in an automotive vehicle.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

1. An apparatus including a co-spiral inductor comprising:
a plurality of turns, each of the plurality of turns being displaced both vertically and horizontally from a next successive turn, wherein the plurality of turns is formed from traces on different metal layers formed on a substrate;
a plurality of insulators configured to electrically insulate each of the plurality of turns; and
a plurality of interconnects configured to couple each of the plurality of turns to at least one other turn.

2. The apparatus of claim 1, wherein the plurality of interconnects are configured to couple each of the plurality of turns in series.

3. The apparatus of claim 1, wherein at least one of the plurality of interconnects is configured to couple at least two of the plurality of turns in parallel.

4. The apparatus of claim 1, wherein the plurality of turns are hexagonal, circular, square, or rectangular in shape.

5. The apparatus of claim 1, wherein the plurality of turns are generally tapered with a first turn of the plurality of turns having a smallest length and a last turn of the plurality of turns having a greatest length.

6. The apparatus of claim 1, wherein each of the plurality of turns is formed on a separate layer from any other turn of the plurality of turns.

7. The apparatus of claim 6, wherein the substrate is part of a flip-chip.

8. The apparatus of claim 7, further comprising a package substrate coupled to the substrate on a first side of the package substrate that faces the co-spiral inductor.

9. The apparatus of claim 8, further comprising a printed circuit board coupled to the package substrate on a second side of the package substrate that is opposite the first side.

10. The apparatus of claim 1, wherein at least two of the plurality of turns have different thicknesses.

11. The apparatus of claim 10, wherein a first turn closest to the substrate has a smaller thickness than a last turn furthest away from the substrate.

12. The apparatus of claim 10, wherein at least one outer turn is formed from at least two stacked metal layers of different metal layers.

13. The apparatus of claim 12, wherein the at least one outer turn has at least one via layer that couples the at least two stacked metal layers.

14. The apparatus of claim 12, wherein at least one of the at least two stacked metal layers is a on a same metal layer as at least one other turn of the plurality of turns.

15. The apparatus of claim 1, wherein the plurality of insulators is formed of one or more of silicon dioxide (SiO₂), an organic polymeric dielectric, polyimide (PI), polynorbornene, benzocyclobutene (BCB), polytetrafluoroethylene (PTFE), Polybenzoxazoles (PBO), or silicone based polymeric dielectrics.

16. The apparatus of claim 1, wherein the plurality of turns is formed of one or more of copper (Cu), silver (Ag), gold (Au), nickel (Ni), platinum (Pl), aluminum (Al), Titanium (Ti), tin (Sn), alloys or combinations thereof.

17. The apparatus of claim 1, wherein the substrate is formed of one or more of silicon (Si), High-resistivity silicon (HRSi), glass, aluminum oxide (Alumina), compounds or combinations thereof.

18. The apparatus of claim 1, wherein the apparatus comprises at least one of a hybrid integrated passive device (HIP), an active component integrated with a HIP, a radio frequency (RF) filter, a RF front end (RFFE) circuit, a power combiner, or a diplexer.

19. The apparatus of claim 1, wherein the co-spiral inductor is formed in a back end of line (BEOL) stack or the BEOL stack and one or more redistribution layers (RDL).

20. The apparatus of claim 1, wherein the apparatus is selected from a group comprising at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, or a device in an automotive vehicle.

21. A method for fabricating an apparatus including a co-spiral inductor, the method comprising:
forming a plurality of turns, each of the plurality of turns being displaced both vertically and horizontally from a next successive turn, wherein the plurality of turns is formed from traces on different metal layers formed on a substrate;
forming a plurality of insulators configured to electrically insulate each of the plurality of turns; and
forming a plurality of interconnects configured to couple each of the plurality of turns to at least one other turn.

22. The method of claim 21, wherein the plurality of interconnects are configured to couple each of the plurality of turns in series.

23. The method of claim 21, wherein at least one of the plurality of interconnects is configured to couple at least two of the plurality of turns in parallel.

24. The method of claim 21, wherein the plurality of turns are hexagonal, circular, square, or rectangular in shape.

25. The method of claim 21, wherein the plurality of turns are generally tapered with a first turn of the plurality of turns having a smallest length and a last turn of the plurality of turns having a greatest length.

26. The method of claim 21, further comprising forming each of the plurality of turns on a separate layer from any other turn of the plurality of turns.

27. The method of claim 21, wherein the substrate is part of a flip-chip.

28. The method of claim 21, further comprising coupling a package substrate to the substrate on a first side of the package substrate that faces the co-spiral inductor.

29. The method of claim 28, further comprising coupling a printed circuit board to the package substrate on a second side of the package substrate that is opposite the first side.

30. The method of claim 21, wherein at least two of the plurality of turns have different thicknesses.

31. The method of claim 30, wherein a first turn closest to the substrate has a smaller thickness than a last turn furthest away from the substrate.

32. The method of claim 30, wherein at least one outer turn is formed from at least two stacked metal layers of different metal layers.

33. The method of claim 32, wherein the at least one outer turn has at least one via layer that couples the at least two stacked metal layers.

34. The method of claim 32, wherein at least one of the at least two stacked metal layers is a on a same metal layer as at least one other turn of the plurality of turns.

35. The method of claim 21, wherein the plurality of insulators is formed of one or more of silicon dioxide (SiO₂), an organic polymeric dielectric, polyimide (PI), polynorbornene, benzocyclobutene (BCB), polytetrafluoroethylene (PTFE), Polybenzoxazoles (PBO), or silicone based polymeric dielectrics.

36. The method of claim 21, wherein the plurality of turns is formed of one or more of copper (Cu), silver (Ag), gold (Au), nickel (Ni), platinum (Pl), aluminum (Al), Titanium (Ti), tin (Sn), alloys or combinations thereof.

37. The method of claim 21, wherein the substrate is formed of one or more of silicon (Si), High-resistivity silicon (HRSi), glass, aluminum oxide (Alumina), compounds or combinations thereof.

38. The method of claim 21, wherein the apparatus comprises at least one of a hybrid integrated passive device (HIP), an active component integrated with a HIP, a radio frequency (RF) filter, a RF front end (RFFE) circuit, a power combiner, or a diplexer.

39. The method of claim 21, further comprising forming the co-spiral inductor in a back end of line (BEOL) stack or the BEOL stack and one or more redistribution layers (RDL).

40. The method of claim 21, wherein the apparatus is selected from a group comprising at least one of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, or a device in an automotive vehicle.
